(19) United States
(12) Patent Application Publication
(10) Pub. No.: US 2018/0168063 A1
(43) Pub. Date: Jun. 14, 2018

(54) SERVER

(71) Applicants: INVENTEC (PUDONG) TECHNOLOGY CORPORATION, Shanghai City (CN); INVENTEC CORPORATION, Taipei City (TW)

(72) Inventors: Hui ZHU, Shanghai City (CN); Jia-Bin WANG, Shanghai City (CN)

(73) Assignees: INVENTEC (PUDONG) TECHNOLOGY CORPORATION, Shanghai City (CN); INVENTEC CORPORATION, Taipei City (TW)

(21) Appl. No.: 15/423,492

(22) Filed: Feb. 2, 2017

(30) Foreign Application Priority Data
Dec. 13, 2016 (CN) 201611147394.9

(51) Int. Cl. H05K 7/14

(52) U.S. Cl. CPC H05K 7/1487; H05K 7/1407

(57) ABSTRACT

A server includes a casing, a motherboard and at least one interface card assembly. The casing has a side surface, an accommodating space, and at least one first fastening hole. The first fastening hole is located on the side surface. The motherboard is disposed in the accommodating space of the casing, and the motherboard includes at least one slot. The interface card assembly includes a main body and a handle. The main body is detachably plugged in the at least one slot. The interface card assembly is electrically connected to the motherboard. The handle is pivoted on the main body and includes a fastening block, and the handle is rotatable relative to the main body so as to have the fastening block and the at least one first fastening hole detachably fastened to each other.

### CROSS-REFERENCE TO RELATED APPLICATIONS

This non-provisional application claims priority under 35 U.S.C. § 119(a) on Patent Application No(s). 201611147394.9 filed in China on Dec. 13, 2016, the entire contents of which are hereby incorporated by reference.

### BACKGROUND OF THE INVENTION

### Technical Field of the Invention

The disclosure relates to a server, more particular to a sever having an interface card assembly which has a handle detachably fastened to a casing.

### Description of the Related Art

A host computer includes multiple slots with different specifications, which are located on the motherboard in the casing of the host computer, for connecting different kinds of interface cards. The interface cards are conventionally fastened in the casing of the host computer by screws, and the ports of the interface cards are plugged into the slots on the motherboard. There is a circuit board located on an inner side of each interface card, and there is a connector located on an outer side of each interface card. The connector is connectable to the circuit board, for an external connection.

### SUMMARY OF THE INVENTION

In an embodiment of the present disclosure, a server includes a casing, a motherboard and at least one interface card assembly. The casing has a side surface, an accommodating space, and at least one first fastening hole. The first fastening hole is located on the side surface. The motherboard is disposed in the accommodating space of the casing, and the motherboard includes at least one slot. The interface card assembly includes a main body and a handle. The main body is detachably plugged in the at least one slot. The interface card assembly is electrically connected to the motherboard. The handle is pivoted on the main body and includes a fastening block, and the handle is rotatable relative to the main body so as to have the fastening block and the at least one first fastening hole detachably fastened to each other.

### BRIEF DESCRIPTION OF THE DRAWINGS

The present disclosure will become more fully understood from the detailed description given hereinbelow and the accompanying drawings which are given by way of illustration only and thus are not intending to limit the present disclosure and wherein:

FIG. 1A is a schematic view of a server in an embodiment of the present disclosure;

FIG. 1B is an exploded view of the server in the embodiment of the present disclosure;

FIG. 2 is a side view of the server in the embodiment of the present disclosure;

FIG. 3 is a schematic view of an interface card assembly in the embodiment of the present disclosure;

FIG. 4 is an exploded view of a main body in the interface card assembly in the embodiment of the present disclosure;

FIG. 5 is a cross-sectional view of a circuit board assembly in the embodiment of the present disclosure;

FIG. 6 is a schematic view of a second circuit board in the circuit board assembly in the embodiment of the present disclosure;

FIG. 7 is a schematic view of a handle of the interface card assembly and a part of a first circuit board in the embodiment of the present disclosure;

FIG. 8 is a schematic view of a part of the second side plate in the embodiment of the present disclosure;

FIG. 9A to FIG. 9D are schematic views of releasing the interface card assembly from the motherboard through the handle in the embodiment of the present disclosure; and

FIG. 10A to FIG. 10D are schematic views of fastening the interface card assembly to the motherboard through the handle in the embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

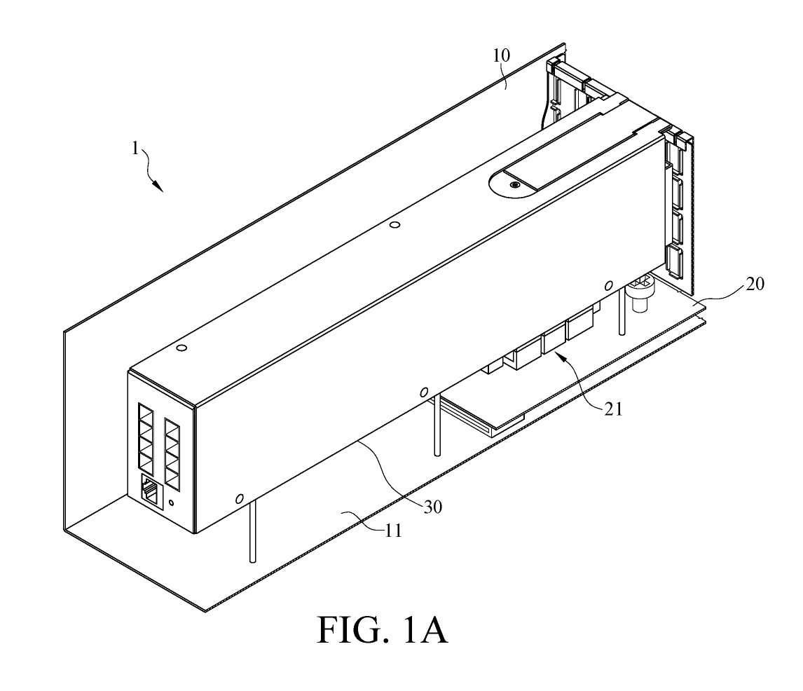

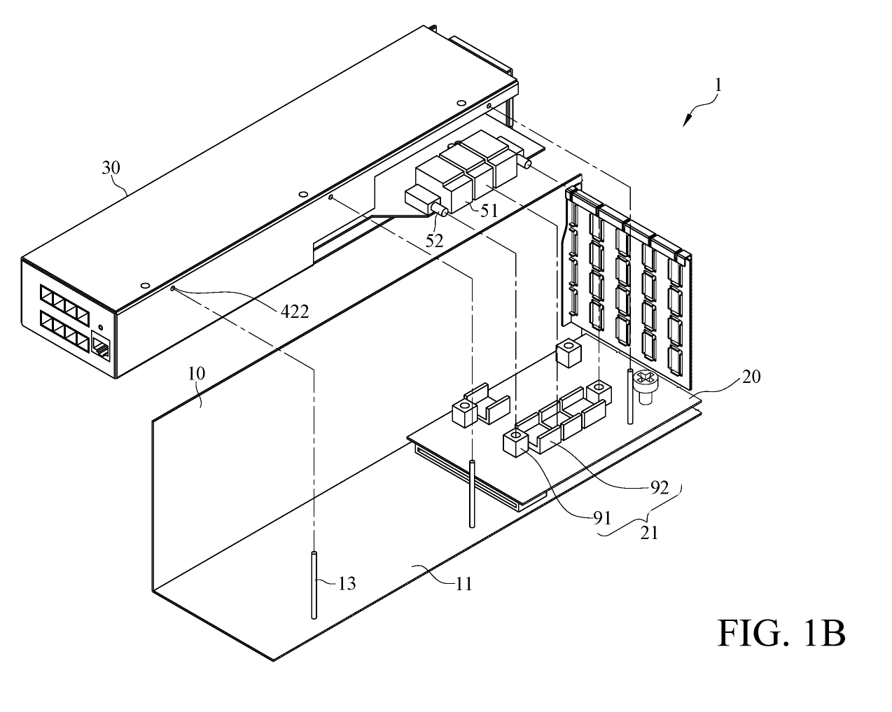

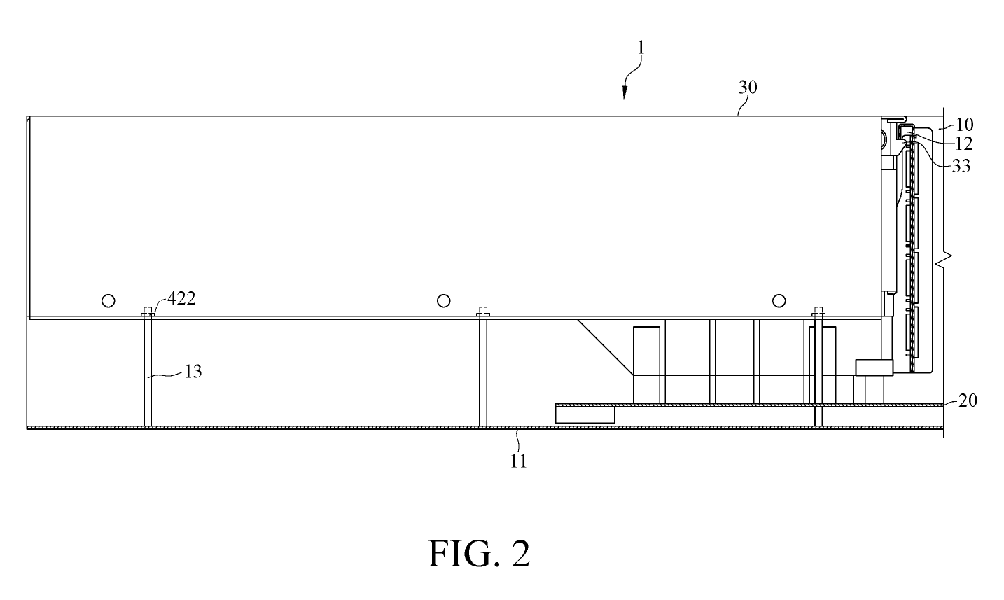

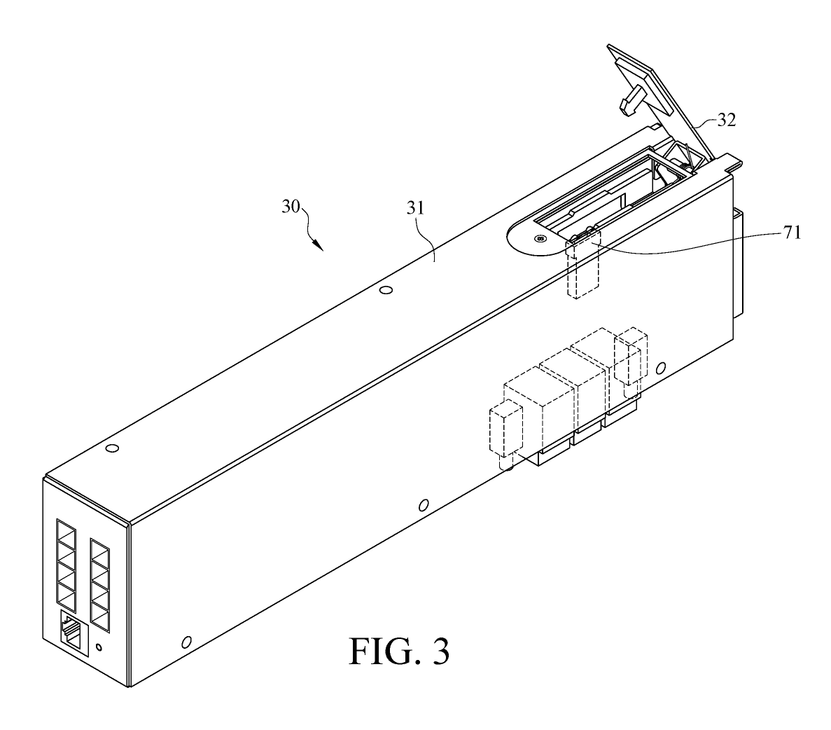

Please refer to FIG. 1 to FIG. 3. FIG. 1A is a schematic view of a server in an embodiment of the present disclosure. FIG. 1B is an exploded view of the server in the embodiment of the present disclosure. FIG. 2 is a side view of the server in the embodiment of the present disclosure. FIG. 3 is a schematic view of an interface card assembly in the embodiment of the present disclosure.

In the embodiment of the present disclosure, the server 1 includes a casing 10, a motherboard 20 and an interface card assembly 30. An accommodating space 11 is formed by the casing 10, and a side surface of the casing 10 has a first fastening hole 12. The motherboard 20 is disposed in the accommodating space 11 of the casing 10, and the motherboard 20 includes at least one slot 21. The interface card assembly 30 includes a main body 31 and a handle 32. The main body 31 is detachably plugged in the slot 21 so that the interface card assembly 30 is electrically connected to the motherboard 20. The handle 32 is pivoted to the main body 31 and includes a fastening block 33. The handle 32 is rotatable relative to the main body 31 so that the fastening block 33 is detachably fastened to the first fastening hole 12. Both the number of the interface card assembly 30 and the number of the first fastening hole 12 are one in this embodiment, but the disclosure is not limited thereto.

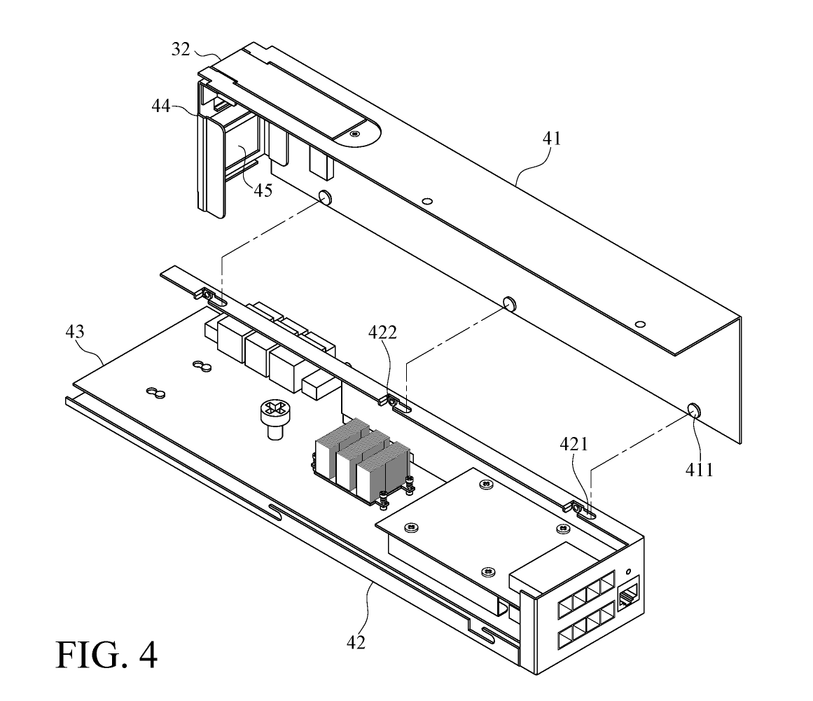

Please refer to FIG. 4. FIG. 4 is an exploded view of a main body in the interface card assembly in the embodiment of the present disclosure. The main body 31 further includes a first side plate 41, a second side plate 42 and a circuit board assembly 43. The circuit board assembly 43 is disposed between the first side plate 41 and the second side plate 42. The first side plate 41 has a fastening pillar 411, and the second side plate 42 has a second fastening hole 421. The second fastening hole 421 of the second side plate 42 is penetrated by the fastening pillar 411 of the first side plate 41 so that the first side plate 41 and the second side plate 42 are fastened to each other. The circuit board assembly 43 is disposed on the second side plate 42, but the present disclosure is not limited thereto. In other embodiments of the present disclosure, the circuit board assembly is disposed on the first side plate 41. The main body 31 further includes a third side plate 44. The third side plate 44, for example, fastens the first side plate 41 and the second side plate 42 with screw so as to improve the structure strength of the interface card assembly 30. The handle 32 is pivoted on the third side plate 44. The third side plate 44 has at least one opening 45 which the cooling air is able to flow through. Please refer to FIG. 1B together. The casing 10 has a guiding pillar 13, and the second side plate 42 has a guiding hole 422. The guiding hole 422 is penetrated by the guiding pillar 13 so that the main body 31 is easily fastened to the casing 10.

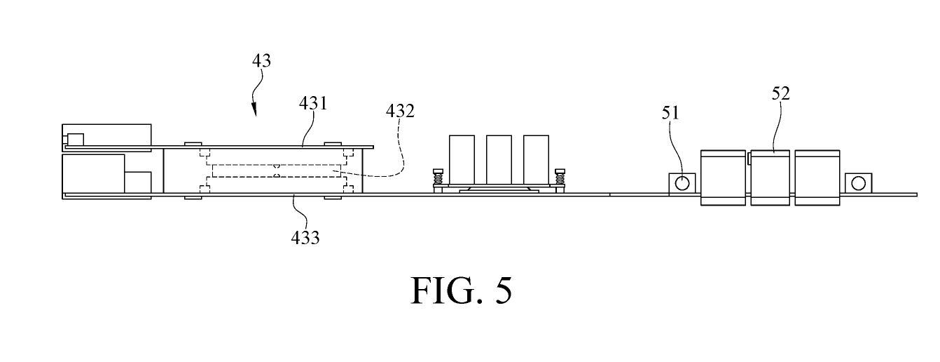

Please refer to FIG. 1B and FIG. 5 together. FIG. 5 is a cross-sectional view of a circuit board assembly in the embodiment of the present disclosure. The circuit board assembly 43 includes a first circuit board 431, a second circuit board 432, and a third circuit board 433. The second circuit board 432 is located between the first circuit board 431 and the third circuit board 433. The third circuit board 433 further includes a conductive pillar 51 and a signal connector 52. A length of the conductive pillar 51 is greater than a length of the signal connector 52. Furthermore, in this embodiment, the at least one slot 21 of the interface card assembly 30 includes a conductive slot 91 and a signal connection slot 92. The conductive pillar 51 is connected to the conductive slot 91, and the signal connector 52 is connected to the signal connection slot 92. As a result, the signal connector 52 is precisely plugged into the signal connection slot 92 by the guidance of the conductive pillar 51.

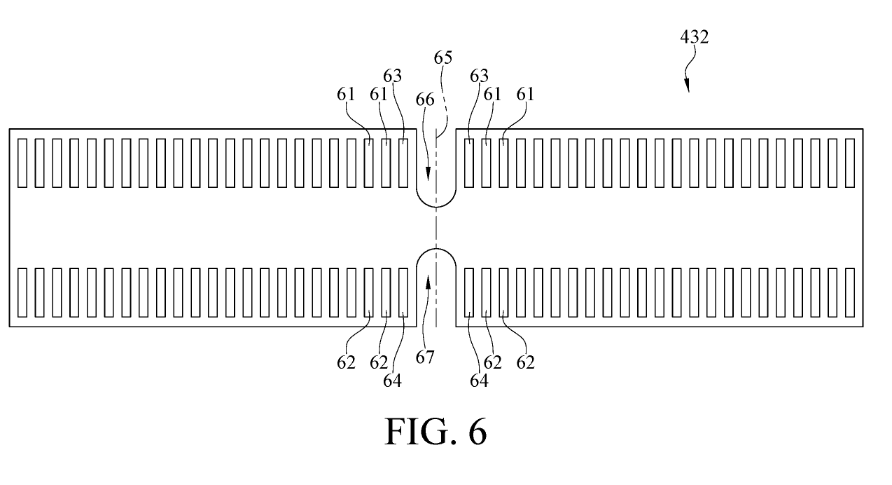

Please refer to FIG. 6. FIG. 6 is a schematic view of a second circuit board in the circuit board assembly in the embodiment of the present disclosure. The second circuit board 432 of the circuit board assembly 43 further includes a plurality of first signal lines 61, a plurality of second signal lines 62, a plurality of first power lines 63, a plurality of second power lines 64 and a central plane 65. The first signal lines 61 are respectively connected to the second signal lines 62. The first power lines 63 are respectively connected to the second power line 64. In this embodiment of the present disclosure, the first power lines 63 are disposed at two opposite sides of a first slit 66, and the first power lines 63 at one side of the first slit 66 and the other first power lines 63 at the other side of the first slit 66 are symmetrical about the central plane 65. The second power lines 64 are disposed at two opposite sides of a second slit 67, and the second power lines 64 at one side of the second slit 67 and the other second power lines 64 at the other side of the second slit 67 are symmetrical about the central plane 65. The first signal lines 61 are disposed at two opposite sides of the first power lines 63, and the first signal lines 61 at one side of the first power lines 63 and the other first signal lines 61 at the other side of the first power lines 63 are symmetrical about the central plane 65. The second signal lines 62 are disposed at two opposite sides of the second power lines 64, and the second signal lines 62 at one side of the second power lines 64 and the other second signal lines 62 at the other side of the second power lines 64 are symmetrical to each other with respect to the central plane 65. As a result, a foolproof effect is achieved.

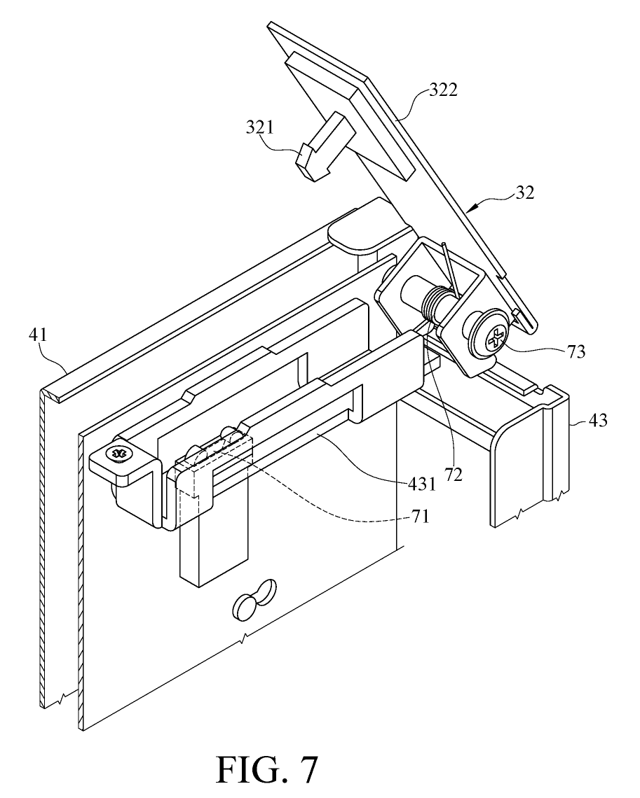

Please refer to FIG. 7. FIG. 7 is a schematic view of a handle of the interface card assembly and a part of a first circuit board in the embodiment of the present disclosure. The first circuit board 431 further includes a fastening recess 71 located on the first side plate 41. The handle 32 has a fastening protrusion 321 located on a surface of the handle 32 close to the first side plate 41. The fastening protrusion 321 is detachably fastened in the fastening recess 71 so that the handle 32 is fastened to the main body 31. When the handle 32 is detached from the main body 31, a first surface 322 of the handle 32 is pressed so that the fastening protrusion 321 is fastened into the fastening recess 71, and therefore, the interface card assembly 30 is fastened to the motherboard 20. When the handle 32 is fastened to the main body 31, the first surface 322 of the handle 32 is pressed so that the fastening protrusion 321 is detached from the fastening recess 71, and therefore, the interface card assembly 30 is detached from the motherboard 20. The handle 32 further has a fixing axis 73 and includes an elastic component 72. The handle 32 is pivoted to the third side plate 44 by the fixing axis 73. An end of the elastic component 72 presses against a side plane of the handle 32, and the other end of the elastic component 72 pressed against a side plane of the first circuit board 431 so as to rotate the handle 32 relative to the main body 31.

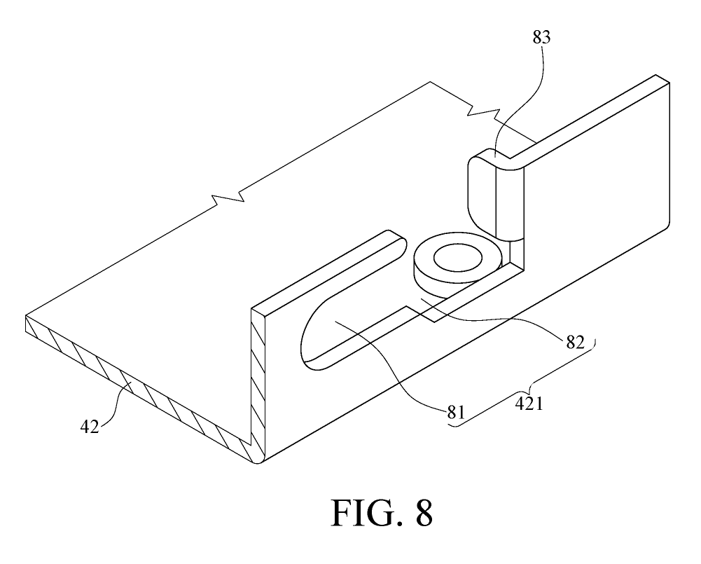

Please refer to FIG. 8. FIG. 8 is a schematic view of a part of the second side plate in the embodiment of the present disclosure. The second fastening hole 421 of the second side plate 42 has a fastening section 81 and a detachment section 82. The fastening section 81 has a first width, and the detachment section 82 has a second width. The second width is greater than the first width. When the first side plate 41 is fastened to the second side plate 42, the detachment section 82 of the second fastening hole 421 is penetrated by the fastening pillar (not shown in the figure), and then the fastening pillar (not shown in the figure) is moved to the fastening section 81 of the second fastening hole 421. Therefore, the fastening pillar (not shown in the figure) of the second side plate 42 is fastened to the second fastening hole 421 of the first side plate 41.

In this embodiment, the second side plate 42 includes a block 83 located away from the fastening section 81 and close to the detachment section 82. When the second fastening hole 421 is penetrated by the fastening pillar (not shown in the figure), a movement of the fastening pillar (not shown in the figure) in the fastening section 81 and the detachment section 82 of the second fastening hole 421 is limited by the block 83 so that the first side plate 41 and the second side plate 42 are fastened to each other.

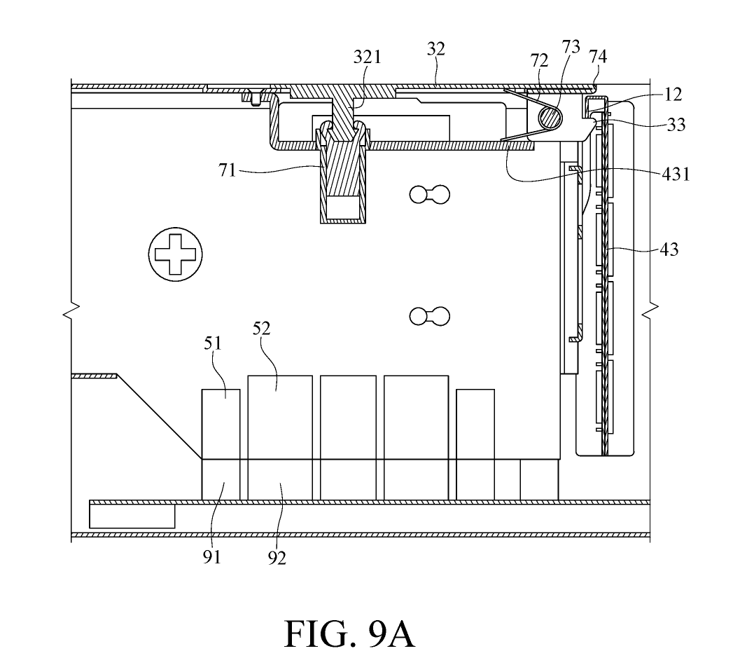

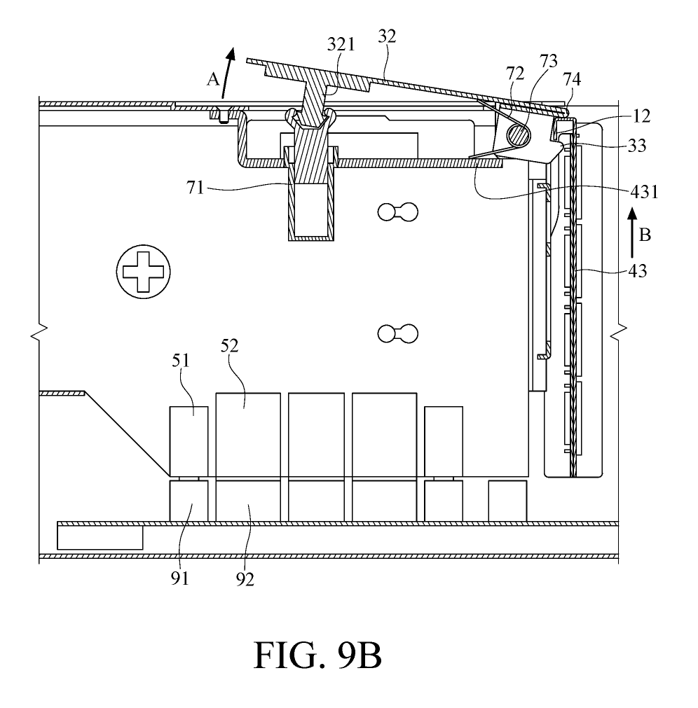

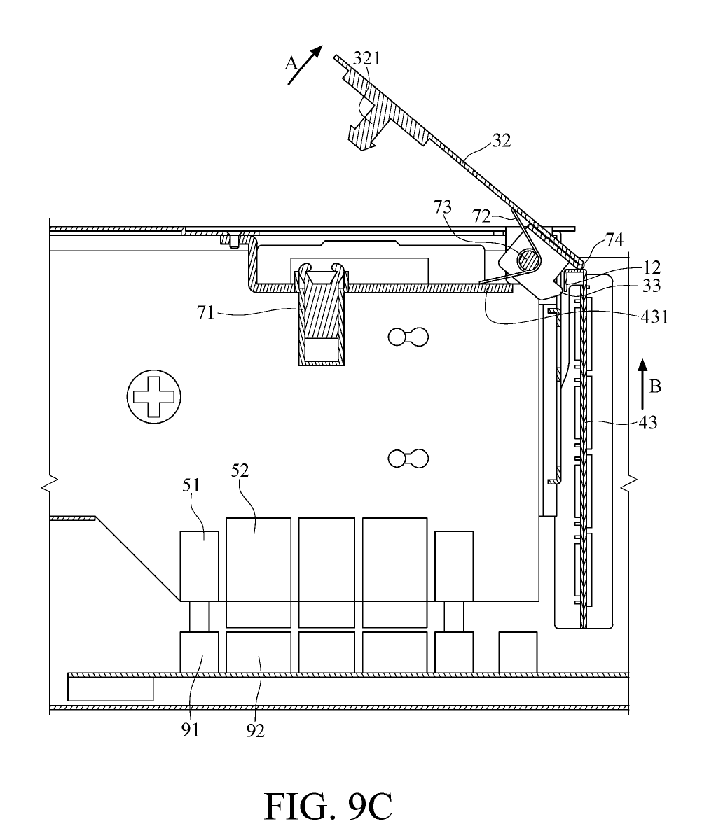

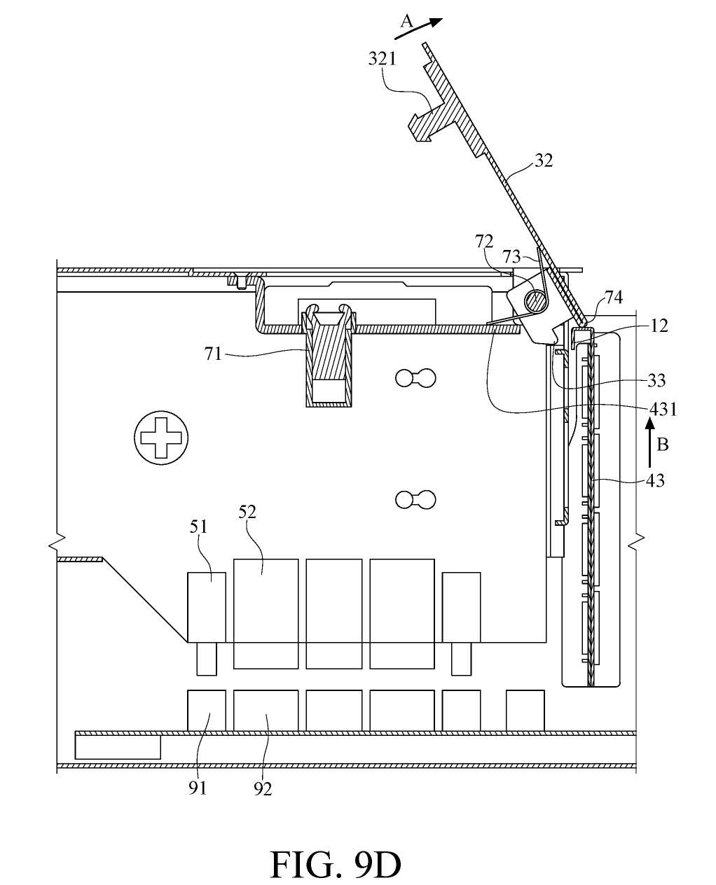

Please refer to FIG. 9A to FIG. 9D. FIG. 9A to FIG. 9D are schematic views of releasing the interface card assembly from the motherboard through the handle in the embodiment of the present disclosure. As shown in FIG. 9A, the fastening protrusion 321 is fastened in the fastening recess 71 so that the handle 32 is fastened to the main body 31. As shown in FIG. 9B, when the handle 32 is pressed by external force, the handle 32 is separated from the main body 31 along the direction of an arrow A by the elastic component 72, so as to separate the conductive pillar 51 and the signal connector 52 from a conductive slot 91 and a signal connection slot 92 along a direction of an arrow B. An end part 74 of the handle 32 and an end of the third side plate 44 are pressed against each other. As shown in FIG. 9C, a force is applied to pull out the handle 32 so that the fastening protrusion 321 and the fastening recess 71 are separated from each other, and the fastening block 33 and the first fastening hole 12 are separated with each other, and the conductive pillar 51 and the signal connector 52 are respectively separated from the conductive slot 91 and the signal connection slot 92. As shown in FIG. 9D, the handle 32 is pulled out to have a maximum angle between the handle 32 and the main body 31 so that the fastening block 33 is away from the first fastening hole 12; thus, the conductive pillar 51 and the signal connector 52 are respectively and totally separated from the conductive slot 91 and the signal connection slot 92 so that the interface card assembly 30 and the slot 21 are separated with each other.

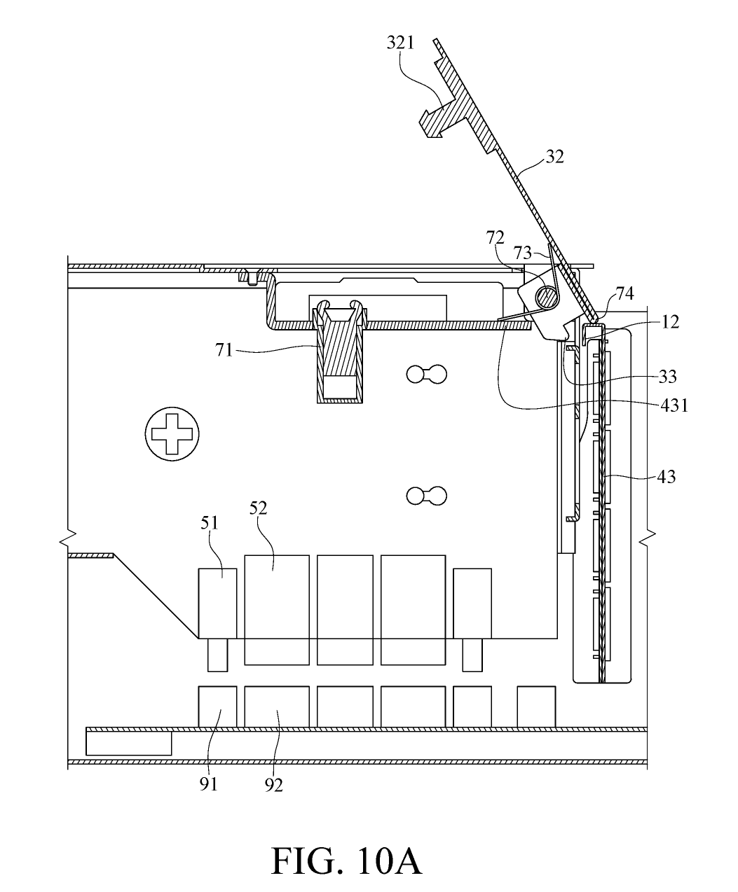

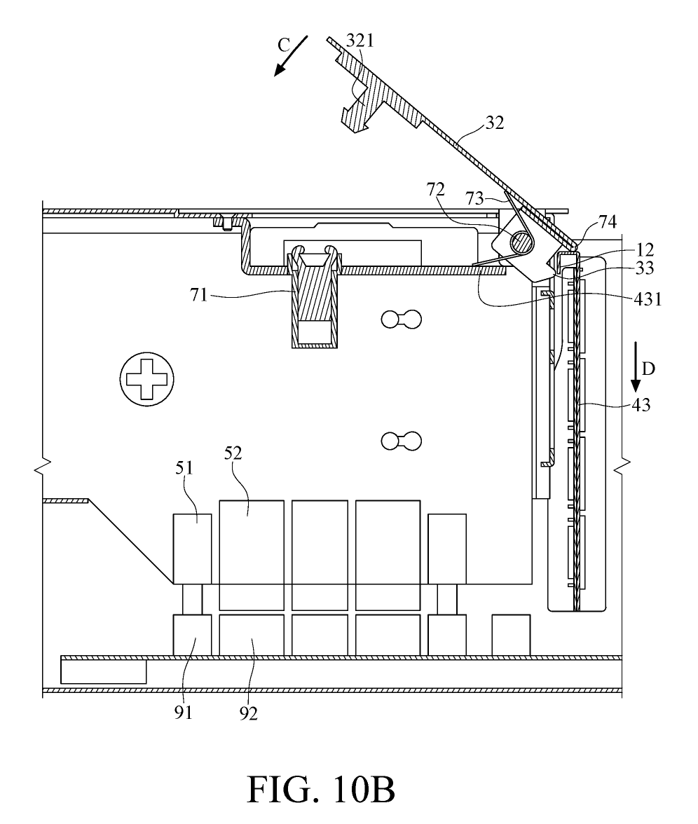

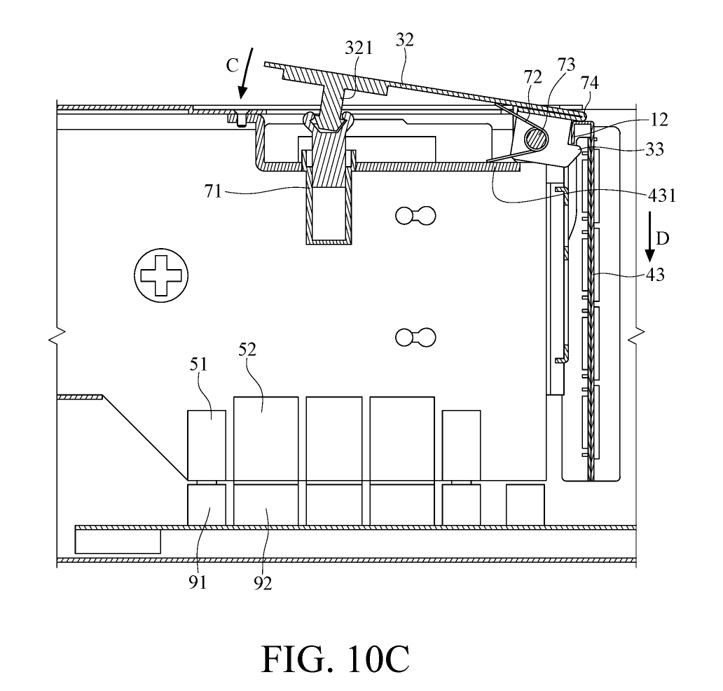

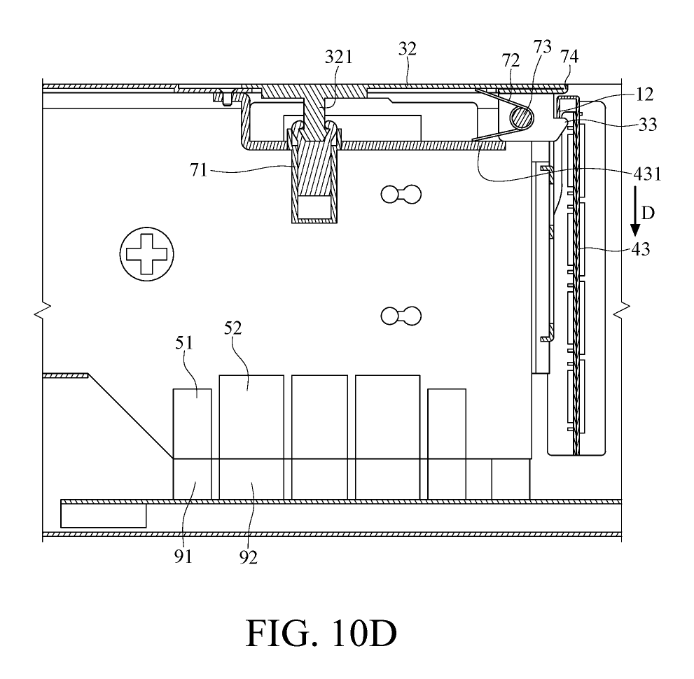

Please refer to FIG. 10A to FIG. 10D. FIG. 10A to FIG. 10D are schematic views of fastening the interface card assembly to the motherboard through the handle in the embodiment of the present disclosure. As shown in FIG. 10A, the maximum angle is between the handle 32 and the main body 31, and the conductive pillar 51 and the signal connector 52 are respectively and totally separated from the conductive slot 91 and the signal connection slot 92. In addition, the end part 74 of the handle 32 and the end of the third side plate 44 are pressed against each other, and the fastening block 33 is away from the first fastening hole 12, and the fastening protrusion 321 is away from the fastening recess 71. As shown in FIG. 10B, the handle 32 is pressed so as to move the fastening protrusion 321 toward the fastening recess 71 along a direction of an arrow C, and the conductive pillar 51 and the signal connector 52 are also respectively moved toward the conductive slot 91 and the signal connection slot 92 along a direction of an arrow D. As shown in FIG. 10C, the fastening protrusion 321 is fastened into the fastening recess 71, and the fastening block 33 is fastened into the first fastening hole 12. As shown in FIG. 10D, the fastening protrusion 321 and the fastening recess 71 are fastened to each other, and the fastening block 33 and the first fastening hole 12 are fastened to each other. The conductive pillar 51 and the signal connector 52 are respectively plugged into the conductive slot 91 and the signal connection slot 92 so that the interface card assembly 30 is fastened in the slot 21.

According to the server in the present disclosure, the handle is rotatable relative to the main body. When the fastening block of the handle is pressed and fastened into the first fastening hole, the fastening block is also moved to press against the casing so that the loading to the user for plugging the interface card assembly to the motherboard is reduced by the lever principle. As a result, even though the interface card assembly is heavy, the interface card assembly is assembled to the motherboard easily and effortlessly by rotating the handle. In addition, when the fastening block of the handle is pressed and detached from the first fastening hole, the fastening block is also moved away from the casing so that the interface card assembly is separated from the motherboard easily and effortlessly by rotating the handle.

What is claimed is:

1. A server, comprising:
a casing having a side surface, an accommodating space, and at least one first fastening hole, and the at least one first fastening hole located on the side surface;
a motherboard disposed in the accommodating space of the casing, and the motherboard comprising at least one slot; and
at least one interface card assembly comprising a main body and a handle, the main body detachably plugged in the at least one slot, the at least one interface card assembly electrically connected to the motherboard, the handle pivoted on the main body, the handle comprising a fastening block, and the handle being rotatable relative to the main body so that the fastening block and the at least one first fastening hole are detachably fastened to each other.

2. The server according to claim 1, wherein the main body of the at least one interface card assembly further comprises a first side plate, a second side plate and a circuit board assembly, the circuit board assembly is located between the first side plate and the second side plate, the first side plate has a second fastening hole, the second side plate has a fastening pillar, and the first side plate and the second side plate are fastened to each other by the second fastening hole and the fastening pillar.

3. The server according to claim 2, wherein the main body further comprises a third side plate, the first side plate and the second side plate are fastened to each other by the third side plate, and the handle is pivoted on the third side plate.

4. The server according to claim 2, wherein the casing comprises a guiding pillar, the second side plate has a guiding hole, and the main body is fastened to the casing by the guiding pillar penetrating through the guiding hole.

5. The server according to claim 2, wherein the circuit board assembly comprises a first circuit board, a second circuit board, and a third circuit board, and the second circuit board is located between the first circuit board and the third circuit board.

6. The server according to claim 5, wherein the third circuit board further comprises a conductive pillar and a signal connector, the at least one slot of the motherboard comprises a conductive slot and a signal connection slot, the conductive pillar is connected to the conductive slot, and the signal connector is connected to the signal connection slot.

7. The server according to claim 5, wherein the second circuit board further comprises a plurality of first signal lines, a plurality of second signal lines, a plurality of first power lines, a plurality of second power lines and a central plane, the plurality of first signal lines are respectively connected to the plurality of second signal lines, the plurality of first signal lines are symmetrical about the central plane, the plurality of second signal lines are symmetrical about the central plane, the plurality of first power lines are respectively connected to the plurality of second power lines, the plurality of first power lines are symmetrical about the central plane, and the plurality of second power lines are symmetrical about to the central plane.

8. The server according to claim 5, wherein the first circuit board is located on the first side plate and has a fastening recess, the handle comprises a fastening protrusion which is located at a surface of the handle close to the first side plate, and the handle is fastened to the main body when the fastening protrusion is detachably fastened in the fastening recess.

9. The server according to claim 2, wherein the second fastening hole has a fastening section and a detachment section which are communicated with each other, the fastening section has a first width, the detachment section has a second width, and the second width is larger than the first width.

10. The server according to claim 9, wherein the second side plate comprises a block away from the fastening section and close to the detachment section.
